(19) United States
(12) Patent Application Publication
(10) Pub. No.: US 2015/0206769 A1
(43) Pub. Date: Jul. 23, 2015

(54) LEAD FRAME BASED SEMICONDUCTOR DEVICE WITH POWER BARS

(71) Applicants: Kesvakumar V.C. Muniandy, Port Klang (MY); Dominic Koey, Kepong Baru (MY); Navas Khan Oratti Kalandar, Petaling Jaya (MY)

(72) Inventors: Kesvakumar V.C. Muniandy, Port Klang (MY); Dominic Koey, Kepong Baru (MY); Navas Khan Oratti Kalandar, Petaling Jaya (MY)

(21) Appl. No.: 14/160,500

(22) Filed: Jan. 21, 2014

(51) Int. Cl. H01L 21/56; H01L 23/00; H01L 23/495

(52) U.S. Cl. CPC H01L 21/56; H01L 23/49503; H01L 23/4952; H01L 24/85

(57) ABSTRACT

A semiconductor device includes a semiconductor die having first and second opposing main surfaces and a die bonding pads on the first main surface, and a conductive member having first and second opposing main surfaces that surrounds the die. The die and the conductive member are encapsulated with a first encapsulant and form an expanded die. The expanded die is mounted on a lead frame having conductive leads, and the conductive leads are electrically coupled to the conductive member, which acts as a power bar, and to the die bonding pads. The conductive member also is electrically coupled to at least one of the die bonding pads. The expanded die and portions of the conductive leads are encapsulated with a second encapsulant.

### BACKGROUND OF THE INVENTION

The present invention is directed to semiconductor packaging and, more particularly, to a method of assembling semiconductor packages using a standard lead frame and a power bar.

Different packages, particularly quad-flat packages (QFPs), often have different power or ground requirements that make it difficult to utilize a standard lead frame during manufacture. As a result, numerous lead frame designs have been provided that are unique to the power ranges needed for the QFP. Even where lead counts are the same, vastly different lead frame designs may be utilized between QFPs due to the power requirements.

It is therefore desirable to provide a method of assembling semiconductor devices that can utilize a standard lead frame design regardless of the power ranges required for the device.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. Notably, certain vertical dimensions have been exaggerated relative to certain horizontal dimensions.

FIG. 1 is a cross-sectional side elevational view of a semiconductor package in accordance with a preferred embodiment of the present invention;

FIG. 2 is an inverted cross-sectional side elevational view of a semiconductor die mounted to a carrier for forming the package of FIG. 1;

FIG. 3 is an inverted cross-sectional side elevational view of the structure of FIG. 2 with conductive members mounted to the carrier;

FIG. 4 is an inverted cross-sectional side elevational view of the structure of FIG. 3 following encapsulation; and

FIG. 5 is an inverted cross-sectional side elevational view of the structure of FIG. 4 following removal of the carrier and singulation.

### DETAILED DESCRIPTION OF THE INVENTION

In one embodiment, the present invention provides a semiconductor device. The semiconductor device includes a semiconductor die having first and second opposing main surfaces and die bonding pads on the first main surface, and a conductive member having first and second opposing main surfaces and that surrounds the die. The die and the conductive member are encapsulated with a first encapsulant and form an expanded die. The expanded die is mounted on a lead frame having conductive leads, and the conductive leads are electrically coupled to the conductive member, which acts as a power bar, and to the die bonding pads. The conductive member also is electrically coupled to at least one of the die bonding pads. The expanded die and portions of the conductive leads are encapsulated with a second encapsulant.

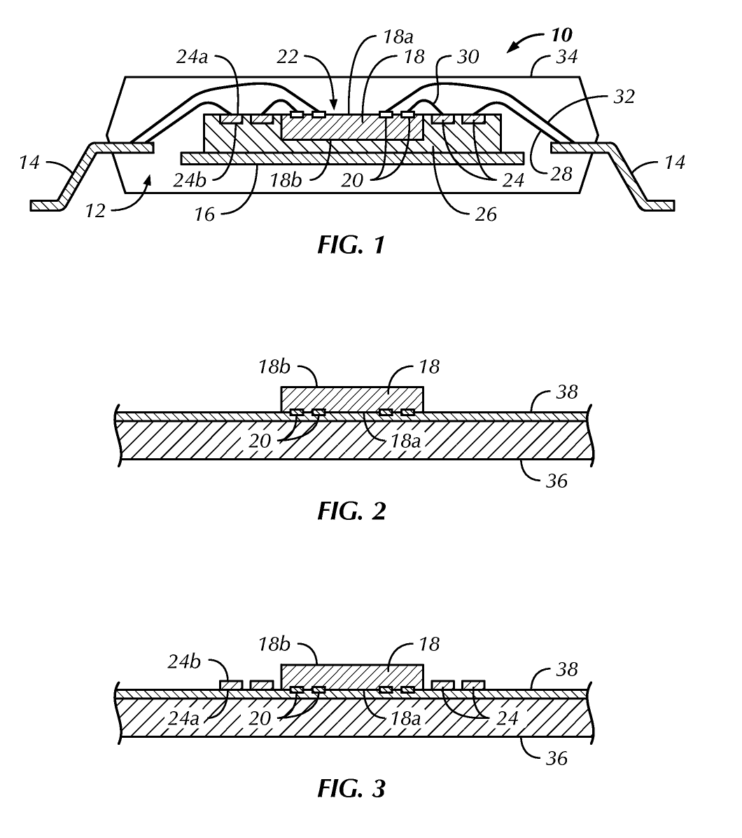

Referring now to the drawings, wherein the same reference numerals are used to designate the same components throughout the several figures, there is shown in FIG. 1 a preferred embodiment of a semiconductor device 10 in accordance with the invention. A lead frame 12 is provided for the semiconductor device 10 that includes a plurality of conductive leads 14 appropriately sized and spaced according to the desired specifications of the completed semiconductor device 10. Each of the conductive leads 14 is preferably made from a conductive material, such as copper (Cu), aluminum (Al), or the like. The plurality of conductive leads 14 may also be coated, alloyed, or pre-plated with a metal layer or layers such as silver (Ag), gold (Au), nickel (Ni), palladium (Pd), tin (Sn), or the like. However, other materials may be used for the conductive leads 14. The number and shapes of the conductive leads 14 may be varied as necessary depending on the end use configurations and other such factors.

The lead frame 12 further includes a support 16, such as a die flag or the like, that is typically radially surrounded by the plurality of conductive leads 14. The support 16 may be made from the same or a different material as the plurality of conductive leads 14, and may be conductive or insulative, as necessary.

The lead frame 12 preferably also at least initially includes a frame or base (not shown) to which the plurality of conductive leads 14 and the support 16 may initially be connected and which is at least partially removed prior to completion of the semiconductor device 10. It is preferred that the lead frame 12 is of a standard design with which, through the present invention, multiple types of devices 10 having different power requirements may be formed.

The semiconductor device 10 further includes a semiconductor die 18 having opposing first and second main surfaces 18a, 18b. The semiconductor die 18 is typically in the form of an integrated circuit (IC) or the like. The semiconductor die 18 may be made from any semiconductor material or combinations of materials, such as gallium arsenide, silicon germanium, silicon-on-insulator (SOI), silicon, monocrystalline silicon, the like, and combinations of the above. Further, the die 18 may implement various types of circuits, such as a processor, a controller, a System on a Chip, or the like, and the circuit may have one or more different power domains.

The semiconductor die 18 preferably includes one or more bonding pads or contacts 20 provided at least on the first main surface 18a thereof, which is preferably the active surface of the semiconductor die 18. The contacts 20 may be made from copper (Cu) and/or other conductive materials, and may be coated, alloyed or pre-plated with a metal layer or layers such as gold (Au), nickel (Ni), palladium (PD), tin (Sn) or the like.

For purposes of facilitating the use of a standard lead frame 12, the semiconductor die 18 preferably forms part of an “expanded die” 22 that is mounted on the support 16 of the lead frame 12. In addition to the semiconductor die 18, the expanded die 22 includes at least one conductive member 24 having opposing first and second main surfaces 24a, 24b. The conductive member 24 is preferably formed from or includes a conductive material such as copper, aluminum, or the like. Multiple conductive members 24 can be used for accommodating multiple power ranges (e.g., for an integrated circuit having multiple power domains).

The at least one conductive member 24 can take the form of at least one ring of conductive material (the ring being circular, oval, square, rectangular, or the like in shape), or other continuous or discontinuous configurations, formed radially surrounding and at least slightly spaced from the semiconductor die 18. The at least one conductive member 24 may also take the form of, for example, one or more embedded ground planes (not shown), such as those described in commonly owned U.S. patent application Ser. No. 13/530,117, the entire contents of which are incorporated by reference herein. The at least one conductive member 24 can also take on other forms, and may include insulating material (not shown), such as a dielectric or polymer material, such as oxide, nitride, or the like.

The semiconductor die 18 and the at least one conductive member 24 are joined together in the expanded die 22 by an encapsulating material 26 that encapsulates at least the second main surfaces 18b, 24b of the semiconductor die 18 and the at least one conductive member 24. The encapsulation material 26 is preferably formed from a mold compound, such as a ceramic material, a polymeric material, or the like, as is known in the art. The first main surfaces 18a, 24a of the semiconductor die 18 and the at least one conductive member 24 are preferably left exposed through the encapsulating material 26 for electrical connection, as will be described in detail below. However, the encapsulating material 26 may alternatively be used to encapsulate the entirety of the semiconductor die 18 and the at least one conductive member 24, and vias or other external contacts (not shown) may be used to allow for electrical connection.

One or more first electrical connectors 28 are provided to electrically couple the at least one conductive member 24 to at least one of the conductive leads 14 of the lead frame 12, while one or more second electrical connectors 30 electrically couple at least one of the contacts 20 of the semiconductor die 18 to the at least one conductive member 24. The first and second electrical connectors 28, 30 are preferably bond wires, such as gold wires or the like, although other types of electrical connectors 28 may be used as well.

In some embodiments, one or more third electrical connectors 32, also preferably in the form of bond wires, are provided to electrically couple contacts 20 of the semiconductor die 18 directly to one or more of the conductive leads 14 of the lead frame 12. For clarity, the third electrical connectors 32 shown in FIG. 1 are coupled to conductive leads 14 that are not visible in the provided view. It is preferred that conductive leads 14 that are used for power, grounding, or the like in the semiconductor device 10 are connected to the contacts 20 via the conductive members 24, while conductive leads 14 for other uses such as data may be directly connected to the respective contacts 20. However, other arrangements may be utilized as well.

The semiconductor device 10 further includes an encapsulant, preferably a packaging material 34, that embeds the electrical connectors 28, 30, 32, the expanded die 22, and portions of the conductive leads 14 of the lead frame 12. The packaging material 34 is preferably formed from a mold compound, such as a ceramic material, a polymeric material, or the like, and may be the same material as or a different material than the encapsulating material 26.

Referring to FIGS. 2-5, a method of assembling the semiconductor device 10 in accordance with a preferred embodiment of the present invention is shown. In FIG. 2, the first main surface 18a of the semiconductor die 18 is attached to a carrier 36 via adhesive tape 38 or the like, as is conventionally known. The method described may be performed on a single semiconductor die 18 or with a plurality of semiconductor dies 18 attached to the same carrier 36.

In FIG. 3, the first main surfaces 24a of the conductive members 24 are attached to the carrier 36 adjacent to the semiconductor die 18. The conductive members 36 can be attached via a pick-and-place (PnP) apparatus or the like.

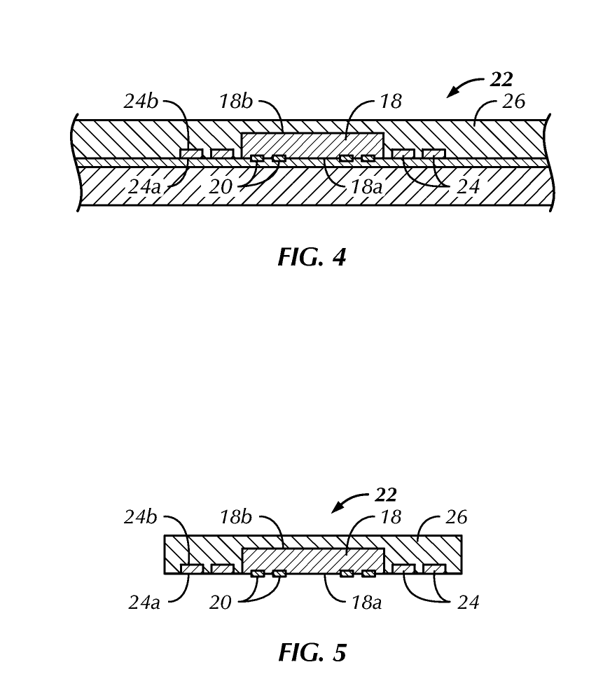

In FIG. 4, the expanded die 22 is formed by encapsulating portions of the semiconductor die 18 and the conductive members 24 with the encapsulating material 26. The arrangement of the first main surfaces 18a, 24a of the semiconductor die 18 and the conductive members 24 on the carrier 36 allows the contacts 20 and portions of the conductive members 24 to remain exposed following the encapsulating process. The encapsulation material 26 may be applied by liquid encapsulation, compression molding, or the like, followed by curing.

In FIG. 5, the expanded die 22 is removed from the carrier 36 and singulated, if necessary. The expanded die 22 is then inverted and mounted to the support 16 of the lead frame 12. The expanded die 22 is preferably bonded to the support 16 using an adhesive, such as an epoxy material. However, other methods of securing the expanded die 22 to the support 16 may be used, such as mechanical or other fasteners or the like.

Following mounting of the expanded die 22, the conductive members 24 are electrically coupled to at least one of the conductive leads 14 and at least one of the contacts 20 is electrically coupled to the conductive members 24 using the electrical connectors 28, 30, 32, as shown in FIG. 1. The electrical coupling is preferably performed by a wire bonding process, as is conventionally known. If necessary, as described above, contacts 20 of the semiconductor die 18 can also be electrically coupled to one or more of the conductive leads 14.

Following electrical coupling, the expanded die 22 and portions of the conductive leads 14 are embedded in the packaging material 34, which can be applied by liquid encapsulation, compression molding, or the like, followed by curing.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and the order of operations may be altered in various other embodiments.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, the word ‘comprising’ or ‘having’ does not exclude the presence of other elements or steps then those listed in a claim. Further, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A method of assembling a semiconductor device, the method comprising:
providing a semiconductor die having first and second opposing main surfaces and a plurality of contacts on the first main surface thereof;
providing at least one conductive member having first and second opposing main surfaces;
forming an expanded die by encapsulating in a first encapsulant at least the second main surfaces of the semiconductor die and the at least one conductive member;
mounting the expanded die on a lead frame having a plurality of conductive leads;
electrically coupling the at least one conductive member to at least one of the conductive leads of the lead frame and electrically coupling at least one of the die contacts to the at least one conductive member; and
embedding the expanded die and portions of the conductive leads in a second encapsulant.

2. The method of claim 1, wherein providing the semiconductor die and the at least one conductive member includes attaching the first main surface of the semiconductor die and the first main surface of the at least one conductive member to a carrier.

3. The method of claim 2, wherein the carrier is removed prior to mounting the expanded die on the lead frame.

4. The method of claim 1, further comprising singulating the expanded die prior to mounting on the lead frame.

5. The method of claim 1, wherein the electrical coupling is performed by wire bonding.

6. The method of claim 1, further comprising electrically coupling at least one of the contacts to at least one of the plurality of conductive leads.

7. The method of claim 1, wherein the at least one conductive member is provided as at least one ring of conductive material or at least one embedded ground plane.

8. The method of claim 1, wherein the at least one conductive member surrounds the semiconductor die.

9. The method of claim 8, wherein the plurality of conductive leads surround the expanded die.

10. A semiconductor device, comprising:
a lead frame having a plurality of conductive leads;
an expanded die mounted on the lead frame, the expanded die comprising:
a semiconductor die having first and second opposing main surfaces and a plurality of contacts on the first main surface thereof,
at least one conductive member having first and second opposing main surfaces, and
a first encapsulating material that encapsulates at least the second main surfaces of the semiconductor die and the at least one conductive member;
a first electrical connector electrically coupling the at least one conductive member to at least one of the conductive leads of the lead frame;
a second electrical connector electrically coupling at least one of the contacts to the at least one conductive member; and
a second encapsulant embedding the expanded die and portions of the conductive leads.

11. The semiconductor device of claim 10, wherein the first main surfaces of the semiconductor die and the at least one conductive member are exposed through the encapsulating material of the expanded die.

12. The semiconductor device of claim 10, wherein at least one of the first and second electrical connectors are bond wires.

13. The semiconductor device of claim 10, wherein the at least one conductive member is at least one ring of conductive material or at least one embedded ground plane.

14. The semiconductor device of claim 10, further comprising a third electrical connector electrically coupling at least one of the contacts to at least one of the plurality of conductive leads.

15. The semiconductor device of claim 10, wherein the at least one conductive member surrounds the semiconductor die.

16. The semiconductor device of claim 15, wherein the plurality of conductive leads surround the expanded die.
